(19) United States
(12) Patent Application Publication
(10) Pub. No.: US 2017/0316824 A1
(43) Pub. Date: Nov. 2, 2017

(54) MULTI-LAYER RESISTIVE MEMORY DEVICES

(71) Applicant: HGST Netherlands B.V., Amsterdam (NL)

(72) Inventor: Daniel Bedau, San Jose, CA (US)

(21) Appl. No.: 15/143,349

(22) Filed: Apr. 29, 2016

(51) Int. Cl. G11C 13/00; H01L 45/00; H01L 27/24

(52) U.S. Cl. CPC G11C 13/0023; H01L 45/1608; H01L 45/146; H01L 45/1233; G11C 13/0002; H01L 27/249; H01L 27/2454; H01L 45/085

(57) ABSTRACT

To provide enhanced data storage devices and systems, various systems, architectures, apparatuses, and methods, are provided herein. In a first example, a multi-layer resistive random access memory (ReRAM) array is provided. Active layers of the array each comprise a plurality of ReRAM elements that each include a gate portion having a gate terminal and a memory cell portion with a source terminal and drain terminal. Insulating layers of the array alternate with the active layers and each comprise an insulating material between adjacent active layers. Wordlines span through more than one layer of the array, with each of the wordlines comprising a column of memory cell portions coupled via source terminals and drain terminals of column-associated ReRAM elements. Bitlines each span through an associated active layer of the array, with each of the bitlines comprising a row of gate portions coupled via at least gate terminals of row-associated ReRAM elements.

### TECHNICAL FIELD

Aspects of the disclosure are related to the field of data storage and resistive random access memory in data storage devices.

### TECHNICAL BACKGROUND

Computer and network data systems such as personal computers, workstations, server systems, and cloud storage systems, typically include data storage devices for storing and retrieving data. These data storage devices can include hard disk drives (HDDs), solid state storage drives (SSDs), tape storage devices, optical storage drives, hybrid storage devices that include both rotating and solid state data storage elements, and other mass storage devices. Recently, new storage technologies have been developed which employ resistive memory elements. These resistive memory elements can include resistive random-access memory (RRAM or ReRAM), which are types of non-volatile random access memory that store data by altering a resistance of a solid-state material. However, ReRAM elements can be difficult to manufacture and incorporate into memory devices. Moreover, arrays of ReRAM employ two-terminal memory elements, which do not integrate well into arrayed architectures.

### OVERVIEW

To provide enhanced data storage devices and systems, various systems, architectures, apparatuses, and methods, are provided herein. In a first example, a multi-layer resistive random access memory (ReRAM) array is provided. Active layers of the array each comprise a plurality of ReRAM elements that each include a gate portion having a gate terminal and a memory cell portion with a source terminal and drain terminal. Insulating layers of the array alternate with the active layers and each comprise an insulating material between adjacent active layers. Wordlines span through more than one layer of the array, with each of the wordlines comprising a column of memory cell portions coupled via source terminals and drain terminals of column-associated ReRAM elements. Bitlines each span through an associated active layer of the array, with each of the bitlines comprising a row of gate portions coupled via at least gate terminals of row-associated ReRAM elements.

In another example, a resistive memory storage array is provided. The array includes a plurality of metallization planes interleaved with a plurality of insulating planes that form a layered stackup of planar material. A plurality of active channels comprises resistive memory material and are disposed vertically through the layered stackup of planar material to establish wordlines of the resistive memory storage array, with each of the active channels enveloped by gate material that isolates the active channels from at least the metallization planes. Individual resistive memory cells are defined by the gate material and proximate portions of the active channels on layers comprising the metallization planes, with the gate material of the resistive memory cells communicatively coupled by associated metallization planes to establish a plurality of bitlines.

In another example, a method of manufacturing a multi-layer resistive random access memory (ReRAM) array is provided. The method includes forming a plurality of metallization planes interleaved with a plurality of insulating planes to establish a layered stackup of planar material. The method includes forming a plurality of active channels comprising resistive memory material disposed vertically through the layered stackup of planar material to establish wordlines of the resistive memory storage array, with each of the active channels enveloped by gate material that isolates the active channels from at least the metallization planes. Individual resistive memory cells are defined by the gate material and proximate portions of the active channels on layers comprising the metallization planes, with the gate material of the resistive memory cells communicatively coupled by associated metallization planes to establish a plurality of bitlines.

### BRIEF DESCRIPTION OF THE DRAWINGS

Many aspects of the disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views. While several embodiments are described in connection with these drawings, the disclosure is not limited to the embodiments disclosed herein. On the contrary, the intent is to cover all alternatives, modifications, and equivalents.

FIG. 1 is a system diagram illustrating a resistive memory array.

FIG. 2 is a system diagram illustrating a resistive memory array.

FIG. 3A illustrates manufacture of resistive memory arrays.

FIG. 3B illustrates manufacture of resistive memory arrays.

FIG. 4 illustrates manufacture of resistive memory arrays.

FIG. 5 is a system diagram illustrating a multi-layered resistive memory array.

FIG. 6 is a system diagram illustrating a multi-layered resistive memory array.

FIG. 7 is a system diagram illustrating a multi-layered resistive memory array.

FIG. 8 includes diagrams illustrating three-terminal resistive memory devices.

FIG. 9 includes diagrams illustrating a multi-layered resistive memory array.

FIG. 10 illustrates manufacture of multi-layered resistive memory arrays.

FIG. 11 illustrates manufacture of multi-layered resistive memory arrays.

FIG. 12 is a block diagram illustrating a resistive memory array controller.

### DETAILED DESCRIPTION

High-density storage devices employ a variety of storage technologies. In the past, magnetic storage devices have been employed, such as hard disk drives with rotating magnetic media. More recently, solid state storage devices, such as flash drives employing NAND flash or other semiconductor-based memory technologies have become popular as associated densities have increased. Other storage technologies, such as optical and non-rotating magnetic technologies are also employed. However, resistive memory technologies have become possible using new materials, which have alterable resistance properties that persist after application of an electric current. These resistive memory devices include memristors and other related devices. Memristors typically comprise two-terminal electrical components, which relate electric charge to magnetic flux linkage, where an electrical resistance of a memristor depends upon a previous electrical current passed by the memristor. Although memristors can be incorporated into non-volatile memories, it has been difficult to incorporate arrays of these memristors into storage devices, in part due to difficulty in achieving addressable memory arrays.

As will be seen herein, various enhanced architectures and devices employ three-terminal resistive memory devices in various linear arrays, two-dimensional arrays, and three-dimensional arrays. In some examples, these three-terminal devices include gate, source, and drain terminals, with the gate terminal employed to alter persistent resistance properties between the source and drain terminals. These three-terminal devices can be referred to as resistive random-access memory (ReRAM) devices or ReRAM elements. Alternatively, a non-volatile memory junction field effect (NVMJFET) transistor element can be employed. As discussed below, these resistive memory elements have three terminals and include resistive memory material in an active channel portion between source and drain terminals. The resistive memory material comprises flux linkage-controlled resistor material.

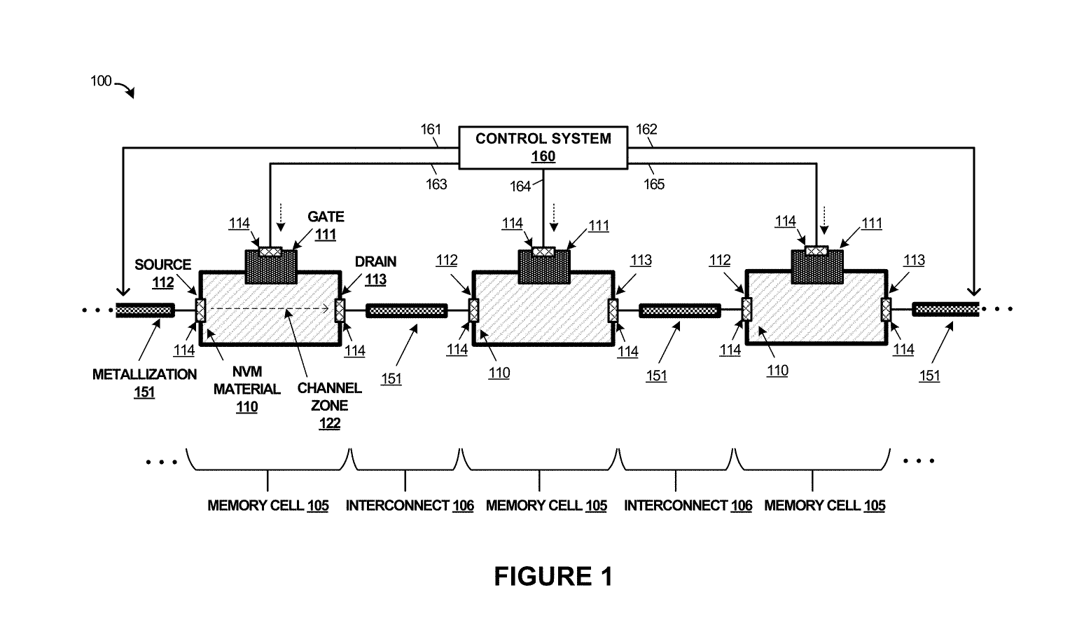

In a first example of a resistive memory storage array, FIG. 1 is presented. FIG. 1 is a system diagram illustrating resistive memory storage array 100. Array 100 illustrates an example linear array of resistive memory elements, each with an associated memory cell 105. Although only three example resistive memory elements are included in FIG. 1, it should be understood that any number can be arrayed into a liner arrangement as shown in FIG. 1. Each resistive memory element comprises a three-terminal configuration that includes gate 111, source 112, and drain 113. Each resistive memory element is interconnected with adjacent resistive memory elements via interconnect elements 106. Control system 160 is included to control each of the resistive memory elements for reading and writing of data bits into associated memory cells.

Turning first to each resistive memory element, an included memory cell 105 comprises non-volatile memory (NVM) material 110 in an associated channel zone 122. NVM material 110 comprises resistive memory material, with resistance properties of the resistive memory material able to be altered using at least an associated gate 111. As mentioned above, each ReRAM element includes gate 111, source 112, and drain 113, with optional terminal material 114 incorporated into each of gate 111, source 112, and drain 113. Each resistive memory element is interconnected by at least metallization 151, which forms conductive links between each resistive memory element.

In write operations, control system 160 can apply a voltage individually to any of the gates over links 163-165 which will alter resistance properties of NVM material 110 in the associated channel zone 122. Altered resistance properties, such as resistances, can be used to store data bits in memory cells, with values of the resistance properties indicating various bit values, such as a binary ‘1’ or ‘0’—although multi-level bit logic can be employed to store many bits per memory cell depending upon the resistance properties.

In read operations, control system 160 can measure a series resistance across all of the memory cells 105 using links 161-162. This series resistance might not indicate the data stored by individual memory cells, as all three memory cells in this example would be measured in series. Control system 160 can also measure individual memory cells by measuring resistances through individual gates, such as by measuring a resistance across link 161 and link 163. Further resistance measurements can be employed, such as across links 161/164 and links 162/165. These various resistance measurements can be processed to identify data bits stored in each memory cell, which can include comparing the series resistance of the entire array to individual gate-selected resistance measurements.

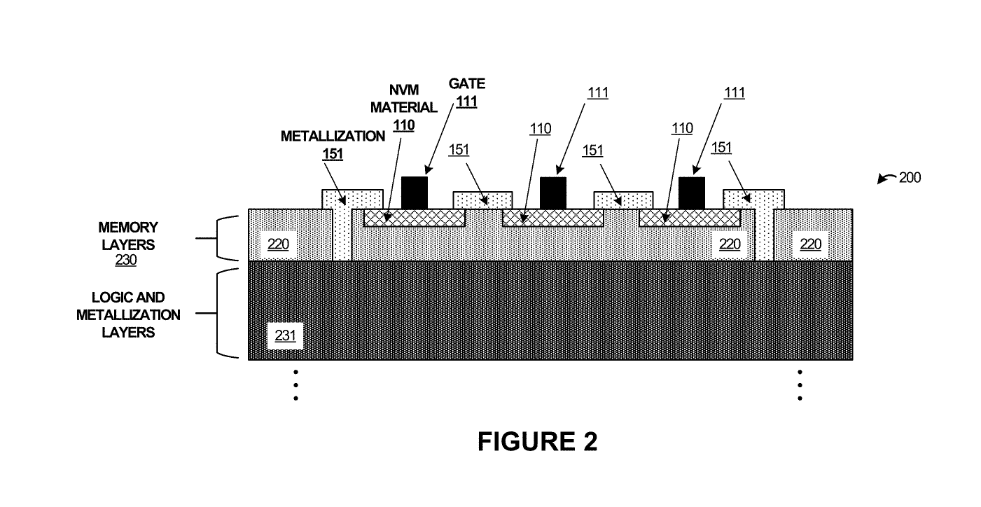

As a further example of an array of resistive memory elements, FIG. 2 is provided. FIG. 2 is a system diagram illustrating memory array 200. Memory layers 230 are formed on one or more logic and metallization layers 231, which can comprise semiconductor-based logic and metal interconnect of a logic circuit, processor, control system, or other elements, which can at least control the elements of memory layers formed on top of layers 231. For example, when a semiconductor wafer is employed for creation of logic circuitry and associated interconnect in layers 231, then resistive memory array 200 can be formed in memory layers 230 on top of layers 231 using techniques found in semiconductor wafer processing and microfabrication, such as photo-lithography, diffusing, deposition, epitaxial growth, etching, annealing, and ion implanting, among others.

Specifically, logical and metallization layers 231 can be formed on a semiconductor substrate, such as a silicon wafer. Memory layers 230 can be built-up from layers 231 to form the memory arrays as discussed herein. Substrate 220 comprises an insulating material, which isolates individual memory cells from each other. NVM material 110 can be diffused, annealed, or ion implanted into substrate 220 to form each memory cell of the resistive memory elements. A gate structure can be formed on top of each memory cell to allow for control of the resistive properties of the associated memory cell. In this manner, array 200 can be built on top of various semiconductor-based circuitry to allow for that circuitry to have nearby memory storage in a compact, layered, arrangement.

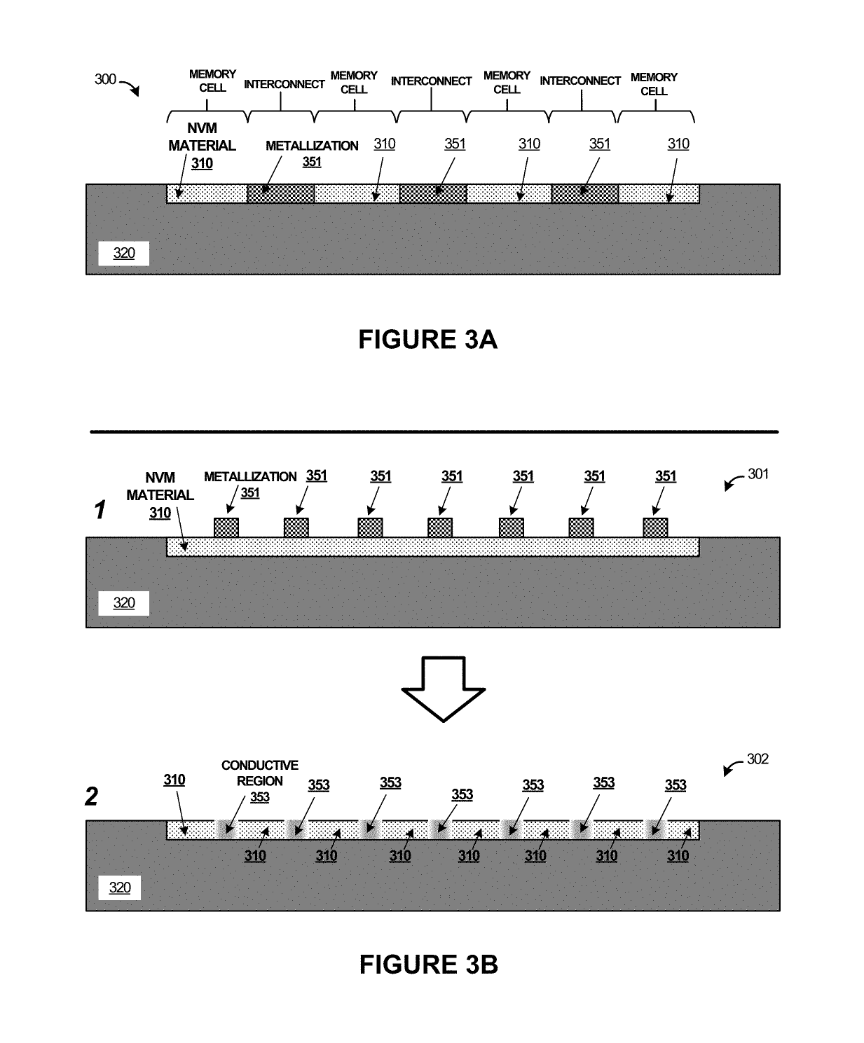

Metallization 151 can be included to interconnect each resistive memory element, with source terminals and drain terminals coupled in a series fashion. Metallization 151 comprises a high conductivity inactive material. In some examples, metallization 151 comprises metal ions implanted into intervening material between resistive memory cells. In other examples, metallization 151 comprises deposited metal or conductive material. FIGS. 3A and 3B show further examples of metallization and other features of resistive memory elements.

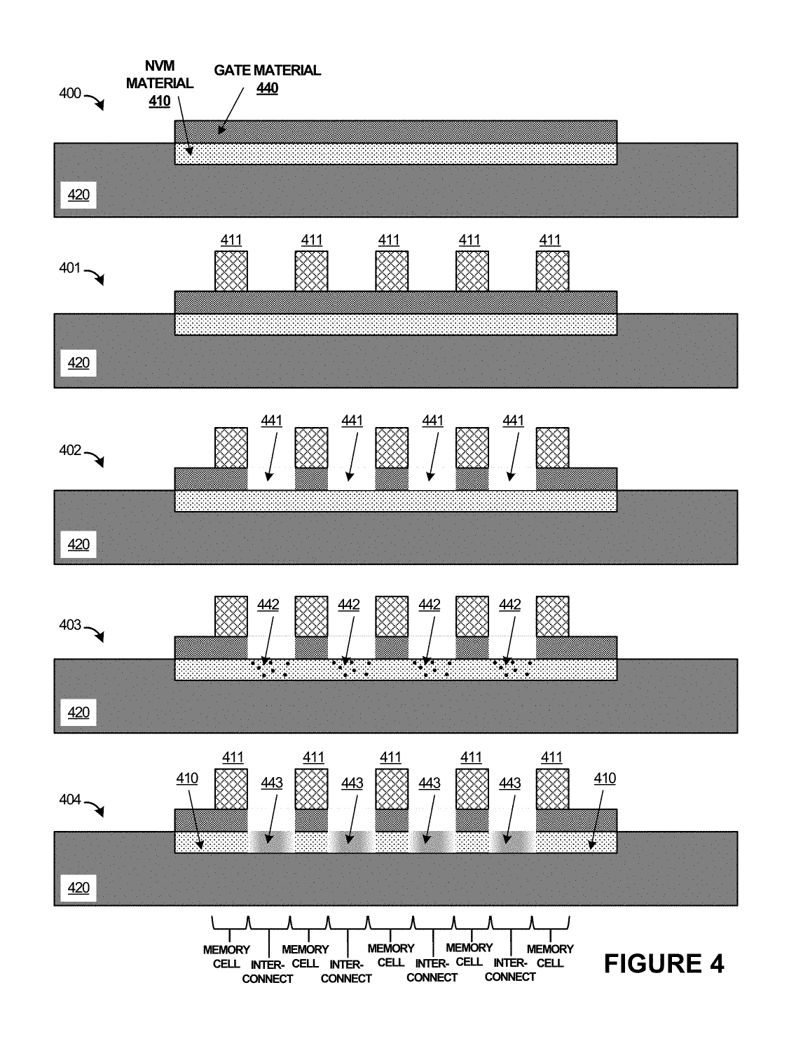

FIGS. 3A and 3B further discuss various manufacturing techniques to form resistive memory arrays. FIG. 3A shows a diffusion or ion implantation technique for creating memory cells, while FIG. 3B shows an annealing technique for creating memory cells. FIG. 4 shows a self-aligned process for creating resistive memory elements. It should be noted that the thicknesses and other dimensions of the various elements, layers, and materials employed herein can depend on properties of the specific materials employed, resistivity properties desired for the devices, manufacturing techniques employed, among other considerations.

Referring first to FIG. 3A, FIG. 3A includes memory array 300, which comprises insulating substrate 320. Substrate 320 can comprise insulating oxide material, such as oxides of silicon or other materials. NVM material 310 is diffused into the surface of substrate 320 to form a strip of NVM material over the entire area of the array. Then, portions of the strip of NVM material are metallized by introducing high-conductivity inactive material in-between areas designated as memory cells. In this manner, the material introduced into substrate 320 can be broken into portions with high-conductivity portions connecting memory cell portions. Gate elements can be formed on top of the memory cell portions.

In another example of FIG. 3A, substrate 320 can be deposited over a sublayer, such as semiconductor layers, and NVM material 310 can be diffused into a top surface of substrate 320. A diffusion into substrate 320 or a complete layer can be formed of the NVM material. Then, a selective diffusion of conductive material is performed to introduce the conductive material into the layer of NVM material at selective regions to interconnect memory cells. Gate material can be patterned on top of the memory cells, and all associated elements can be interconnected with control circuitry, such as within the sublayer of semiconductor.

In one example, the resistive memory material comprises a first oxide of tantalum with an associated first ‘x’ quantity of oxygen atoms (TaOₓ), the conductive material comprises a second oxide of tantalum with an associated second ‘y’ quantity of oxygen atoms (TaO_{y}), where ‘y’ is an integer less than ‘x’. Likewise, the substrate can comprise an insulating oxide of tantalum, such as Ta₂O₅. In other words, the resistive memory material can comprise TaOₓ, where the conductive material comprises TaO_{y} with y comprising an integer less than x, and where the substrate comprises Ta₂O₅

FIG. 3B shows an alternate manufacturing process. In configuration 301, NVM material 310 has been introduced into substrate 320, such as mentioned above. Metallization 351 is patterned onto the surface of NVM material 310, and then an anneal process is performed to bring metallization 351 into the NVM material to make those portions of the NVM material permanently conductive. Instead of an anneal process, ion implantation or chemical reduction can be used. Gate material can be patterned on top of the memory cells, and all associated elements can be interconnected with control circuitry, such as within the sublayer of semiconductor.

FIG. 4 illustrates another example manufacturing process. In a first step 400, a substrate 420 is formed, such as on top of a sublayer of semiconductor circuitry or metallization associated with the semiconductor circuitry. A layer of NVM material 410 is deposited on top of or into substrate 420. Then gate material 440 is layered on top of NVM material 410. In step 401, wordline material 411 is patterned on top of gate material 440 as shown in FIG. 4. In step 402, etching processes create voids 441 to define gate structures with attached wordline material 411. Step 403 illustrates ion implantation of conductive material 442 into the spaces between memory cells. This ion implantation is self-aligned due to the existing gate structures and wordline material. Finally, step 404 illustrates a diffusion step, which makes NVM material inactive to form interconnect 443 and establishes low resistance electrodes between memory cells formed by the active NVM material under each gate structure.

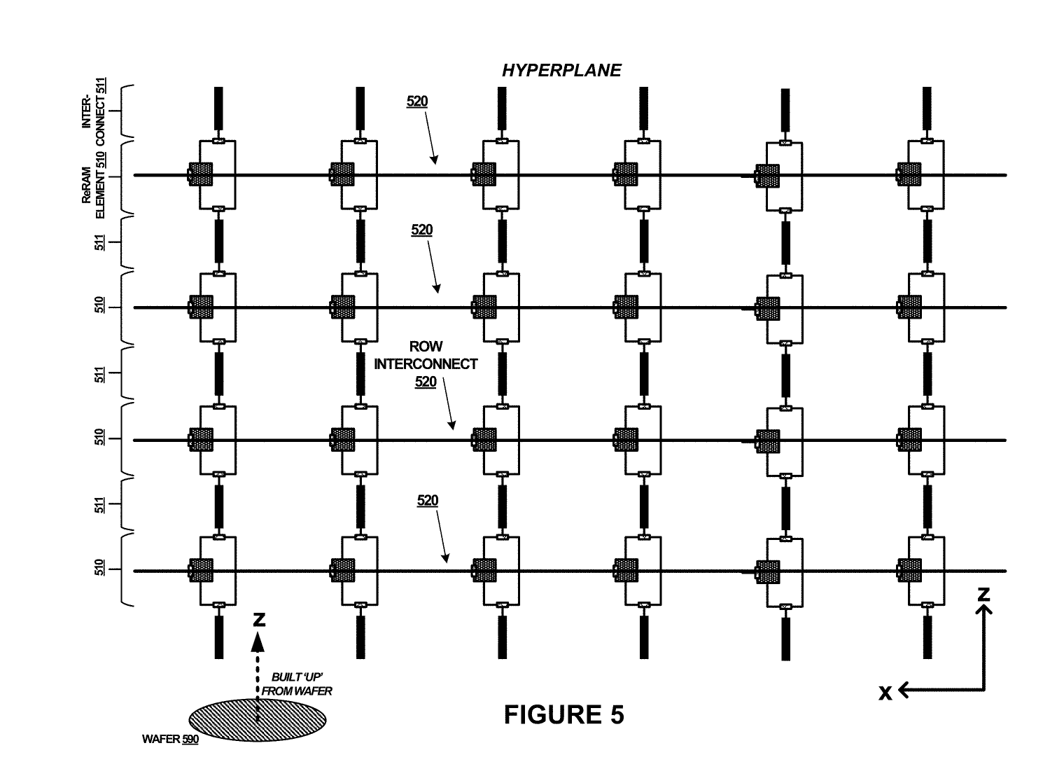

FIG. 5 is provided to illustrate a two-dimensional array of resistive random access memory (ReRAM) elements 510, which form a hyperplane in FIG. 5. Six columns in the ‘z’ direction of ReRAM elements are shown, with gate portions of each resistive memory element coupled over row interconnects 520 in the ‘x’ direction. In some examples row interconnects 520 comprise wordlines. ReRAM elements of a particular column are interconnected in series with interconnect 511. In some examples, interconnect 511 comprises bitlines.

FIG. 5 can illustrate an array of vertically-layered columns built up from a wafer, such as in the vertical ‘z’ direction from wafer 590. Further examples below illustrate further examples of this. In alternative examples, FIG. 5 can illustrate a top-view of a 2-D plane of ReRAM elements connected with wordlines and bitlines, with the ‘x’ and ‘z’ direction lying parallel to a surface of wafer 590.

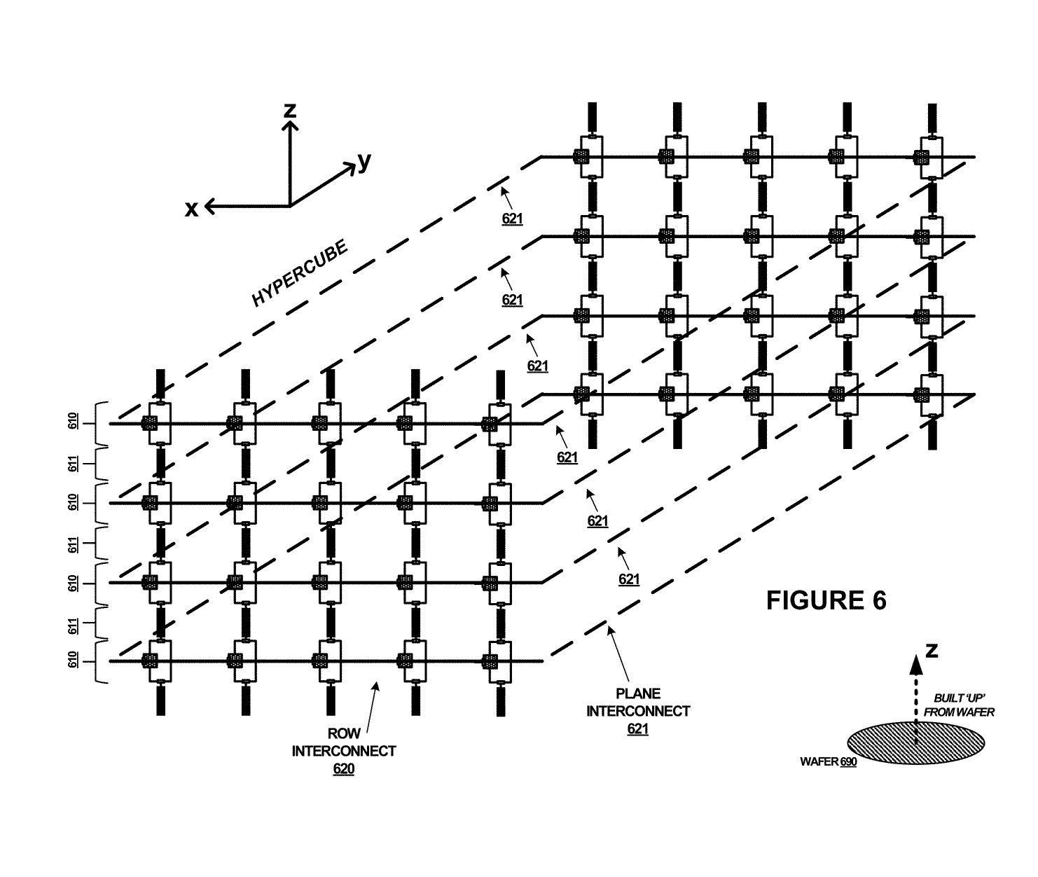

FIG. 6 illustrates a multi-layered, three-dimensional arrangement of ReRAM elements 610 interconnected in columns by interconnect 611. FIG. 6 shows a hypercube arrangement with at least two hyperplanes of ReRAM elements connected via plane interconnect links 621. Plane interconnect links 621 and row interconnect links 620 can form individual wordlines for each plane that is formed along the vertical axis. Interconnect 611 can form individual bitlines. FIG. 6 can thus illustrate an array of vertically-layered planes built up from a wafer, such as in the vertical ‘z’ direction from wafer 690.

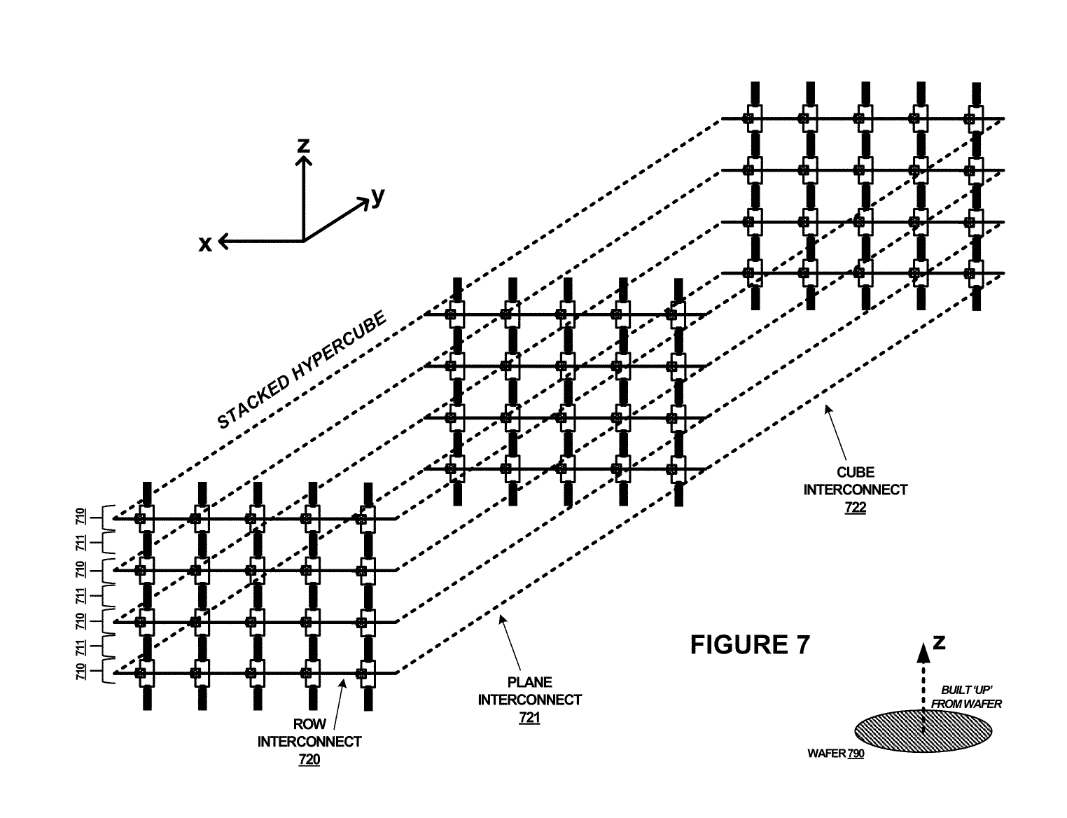

FIG. 7 illustrates a multi-layered, three-dimensional arrangement of ReRAM elements 710 interconnected in columns by interconnect 711. FIG. 7 shows a stacked hypercube arrangement with at least two hypercubes of ReRAM elements connected via cube interconnect links 722. Cube interconnect links 722, plane interconnect links 721, and row interconnect links 720 can form individual wordlines for each plane that is formed along the vertical axis. Interconnect 711 can form individual bitlines. FIG. 7 can thus illustrate an array of vertically-layered planes built up from a wafer, such as in the vertical ‘z’ direction from wafer 790.

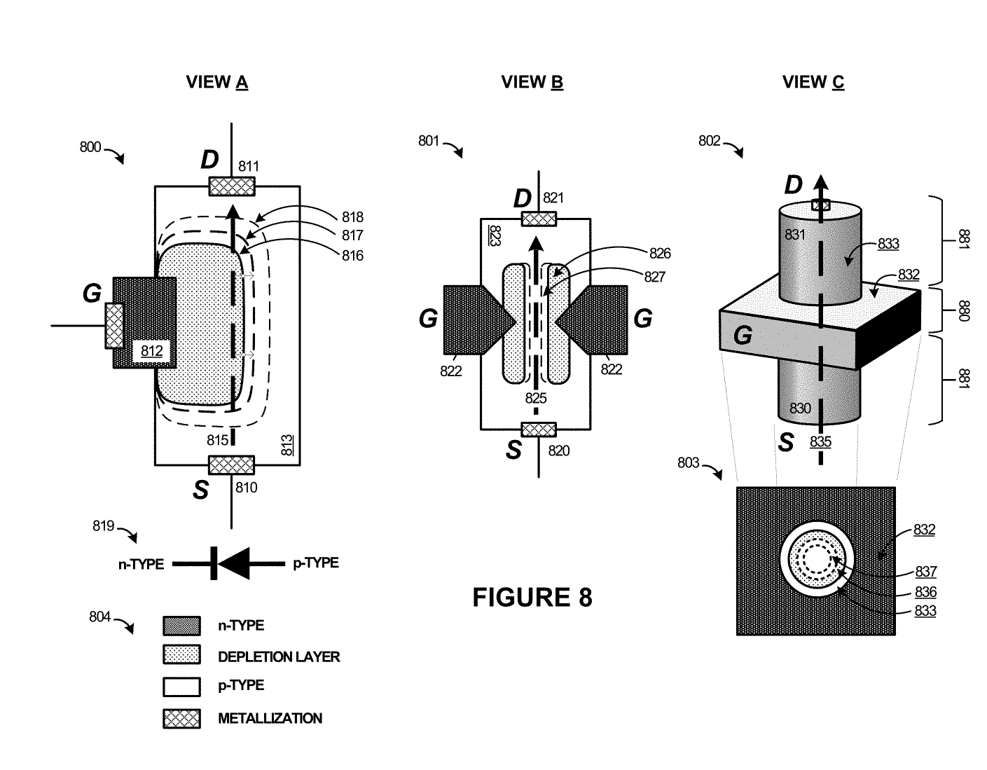

FIG. 8 includes various views illustrating three-terminal resistive memory devices. In a first view ‘A’, a schematic representation of a three-terminal resistive memory device 800 is shown. In a second view ‘B’, a side-view sectioned representation of a 3D three-terminal resistive memory device 801 is shown. In a second view ‘C’, an isometric view of a 3D three-terminal resistive memory device 802 is shown, along with a top view to illustrate various elements of device 802. Devices 800-802 can each comprise ReRAM devices as discussed above, which can also be referred to as a non-volatile memory junction field effect (NVMJFET) transistors. Although each of the gate/source/drain elements in FIG. 8 includes a conductive terminal portion indicated by the rectangular crosshatching, in some examples these conductive terminal portions can be omitted. When employed, the conductive terminal portions can comprise metallized material or metal material, among other material, such as polycrystalline silicon material.

Referring first to view A, device 800 includes a source element (S) 810, a drain element (D) 811, a gate element (G) 812, and an active channel 815 formed in memory cell material 813. Gate 812 might comprise a material that forms a rectifying junction with the material of memory cell 813, which isolates the gate and acts as a selector. As shown in legend 804, the gate material can comprise n-type semiconductor, such as an n-type polycrystalline silicon material. The memory cell 813 might comprise a p-type material, which would form a PN rectifying junction from memory cell-to-gate, as shown in FIG. 8. PN junctions can be fabricated not only from classical semiconductors, but also from oxidic materials. When PN junctions are employed, a resistance level can be measured through the gate associated with a memory cell, as current can flow from the resistive memory material of the channel through the gate, but not in reverse due to the PN junction. In other examples, no PN rectifying junction is formed between gate and channel. In this case, the gate is not electrically isolated from the channel, and resistance values for a memory cell can be measured from gate-to-channel.

In a non-memory FET or JFET devices, voltage applied to a gate element controls current flow between source and drain. However, these non-memory FET devices, when the gate voltage is removed, then behavior between the source and drain returns to an inactive state. Thus, a non-memory FET can be considered a voltage controlled resistor. In the resistive memory devices herein, such as shown in device 800, a structure similar to a FET is shown however instead of being a voltage controlled resistor, the memory-enabled FET is a flux linkage controlled resistor.

By applying a gate (G) 812 voltage, a depletion or enhancement zone moves in and out of an active channel between source (S) 810 and drain (D) 811 and affect a resistance measured across active channel 815 between source 810 and drain 811. This depletion of enhancement zone persists after a voltage is removed from the gate, and thus a memory effect is achieved. In view A, three different encroachments of a depletion layer or depletion zone are shown, which can correspond to different voltage levels applied to gate 812. A first depletion layer configuration 816 corresponds to a first voltage level applied to gate 812, a second depletion layer configuration 817 corresponds to a second voltage level applied to gate 812, and a third depletion layer configuration 818 corresponds to a third voltage level applied to gate 819. The level of encroachment of the depletion layer into memory cell 813 can correspond to a different bit level or data stored in the memory cell. In some examples, a binary representation is employed, with only a ‘1’ and ‘0’ configuration for memory cell. In other examples, a multi-bit representation is employed, with graduated levels of depletion layers corresponding to various data bits. Thus, each memory cell can store one bit or multiple bits, depending upon desired operation and material composition.

The resistive memory material of memory cell 813, which can form channel 815, can be composed of various materials, typically a flux linkage controlled resistor material. In one example, the resistive memory material comprises an oxide of tantalum with an associated ‘x’ quantity of oxide portions (TaOₓ), which is further discussed in an example above. Other examples can have the resistive memory material comprising doped CuInO₂, simple or complex transition metal oxides (e.g. PCMO, HfOx, TaOx, RuOx), delafossites, NiO, TiO₂, ZrO₂, or mixed oxides with Yttrium and Scandium, WOx. Further example resistive memory materials can include ones formed with Mott transition materials or Schottky barrier materials. Other materials are possible, including combinations thereof.

Referring now to view B, which shows a cross-sectioned view of a vertical ReRAM device, device 801 includes a source element (S) 820, a drain element (D) 821, a gate element (G) 822, and a memory cell 823. This view illustrates a vertically-oriented ReRAM device, such as shown in view C, among others. In view B, gate 822 surrounds a central memory cell 823, with gate 822 comprising a ring or cubic shape that envelops a central spire of memory cell 823. The shape of the gate material can vary so as to not be protruding into memory cell 823 in some examples. Example depletion layers 826 and 827 are shown in view B to illustrate how channel 825 might be affected by changes in voltage applied to gate 822.

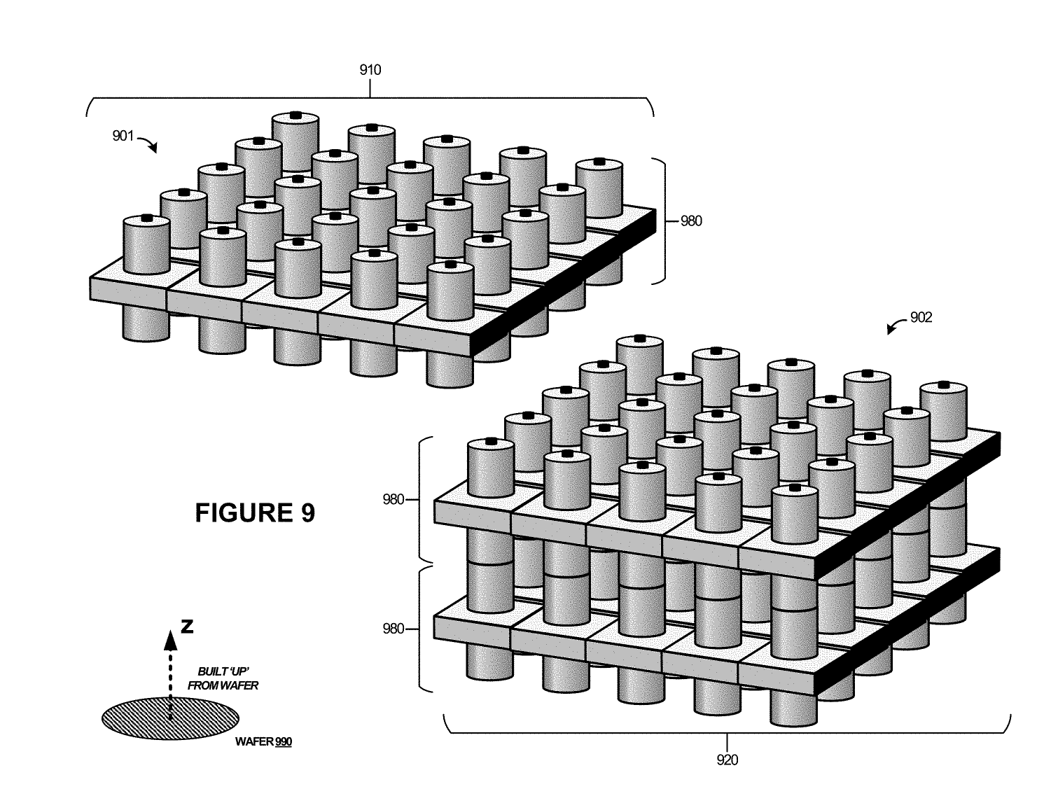

Referring now to view C, which shows an isometric view of a three-dimensional (3D) ReRAM element, device 802 includes a source element (S) 830, a drain element (D) 831, a gate element (G) 832, and a memory cell 833. A top or bottom view 803 is also included to show a cross-sectional view of the internals of device 802. As can be seen in view C, gate 832 surrounds a central memory cell 833, which spans from source 830 to drain 831 to provide active channel 835. Example depletion layers 836 and 837 are shown in view C to illustrate how channel 835 might be affected by changes in voltage applied to gate 832. In some examples, view B can be representative of a side view cross-section of device 802. As will be seen in FIG. 9, these devices 802 can be formed into a layered arrangement of planes, which advantageously allow for high-density packing of memory elements.

The active region for storing data in device 802 can be just proximate to gate 832, such as indicated by region 880 in FIG. 8. Interconnect portions can comprise regions 881 in FIG. 8. In such examples, source 830 and drain 831 would be located nearer to the gate portion and active region. However, in other examples, active region can span one or more portions of regions 880-881, including the entirety of regions 880-881.

FIG. 9 illustrates two isometric views of 3D-stacked resistive memory elements, such as device 802 in FIG. 8. In view 901, a single layer 980 or single plane of ReRAM devices are arranged into array 910, with gate portions connected to form an electrically connected plane which can comprise a ‘wordline’ of the array. Vertical connections through each ReRAM device comprise bitlines. In other examples, rows of ReRAM devices can be employed with wordlines coupling individual rows of ReRAM devices instead of an entire plane of devices. As will be seen below, these devices can be layered using various micro-manufacturing techniques, such as photo-lithography, deposition, epitaxial growth, etching, annealing, diffusion, ion implantation, and other techniques.

Multiple planes or layers of devices can be achieved, such as shown in view 902. View 902 includes at least two layers 980 or planes of ReRAM devices are arranged into array 920, with gate portions of each layer connected to form electrically connected planes which can comprise ‘wordlines’ of the array. Vertical connections through ReRAM devices comprise bitlines. In other examples, rows of ReRAM devices can be employed with wordlines coupling individual rows of ReRAM devices instead of an entire plane of devices.

The quantity of layers or planes is limited only by the material processes and manufacturing techniques employed, and can number in the dozens or higher. Thus, a high-density, 3D stacked, memory array can be created. In one example, the layers are built up from wafer 990 in the vertical or ‘z’ direction to form columnar bitlines and planar wordlines, allowing for efficient addressability of the ReRAM devices for reading and writing.

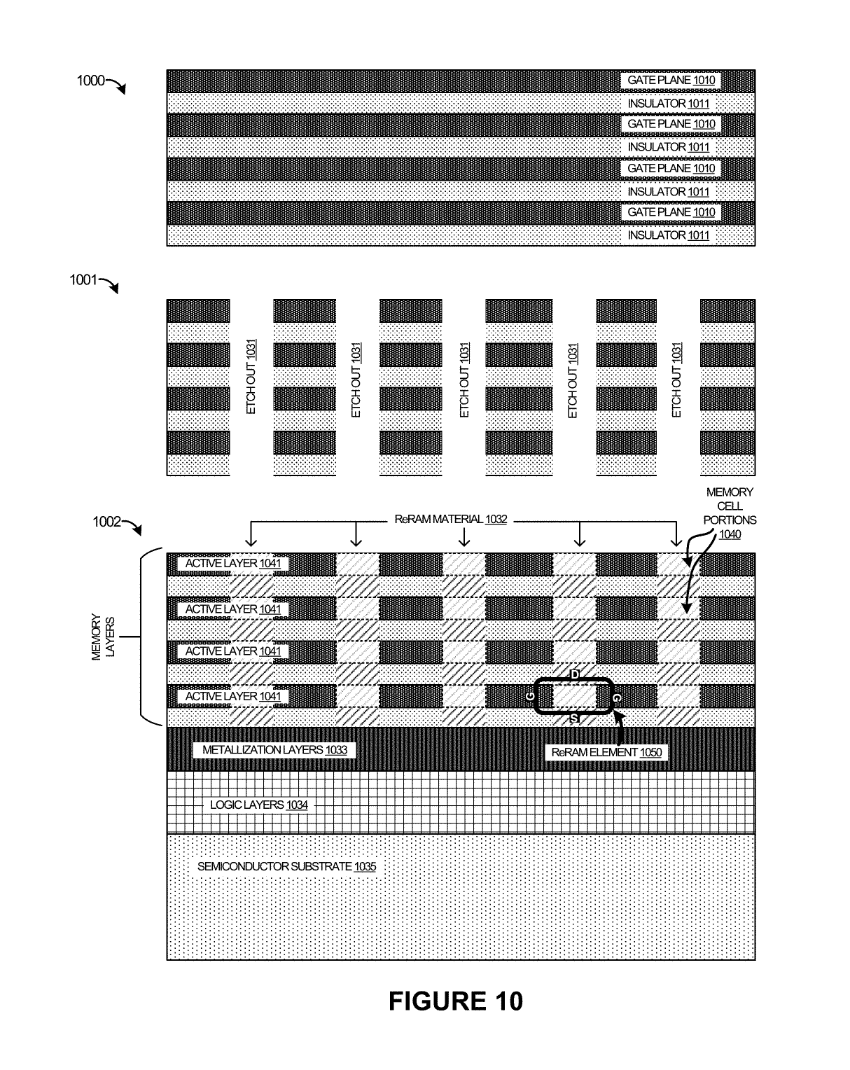

FIG. 10 illustrates an example manufacturing process for a multi-layered or 3D resistive memory array. The compositions of each of the elements of FIG. 10 can comprise any of the materials mentioned herein for associated use in gate materials, insulator materials, resistive memory materials, and metallization materials. In a first view, 1000, a series of interleaved layers is formed onto a substrate, with insulator layers 1011 alternating with gate plane layers 1010. As seen in view 1002, these layers can be formed onto a sublayers comprising metallization layers 1033, logic layers 1034, and further substrates such as semiconductor substrate 1035 or a semiconductor wafer. The sublayers are omitted in views 1000 and 1001 for clarity.

In view 1001, etch-outs 1031 are formed by etching out material vertically through the gate planes and insulator planes for form columnar voids through the memory layers. Then, in view 1002, resistive memory material (ReRAM material 1032) is filled into the voids created by etch-outs 1031, such as by various deposition, epitaxial growth, or other techniques discussed herein.

View 1002 shows completed ReRAM structures in a multi-layered or 3D stacked array. Active layers 1041 of the multi-layer ReRAM array each comprise a plurality of ReRAM elements 1050 that each include a gate portion formed from material of the gate plane. Each of the ReRAM elements have a gate terminal (G) and a memory cell portion 1040 with a source terminal (S) and drain terminal (D). Insulating layers 1011 of the multi-layer ReRAM array alternate with the active layers 1041 and insulating material is included between adjacent active layers. A plurality of wordlines span through more than one layer of the multi-layer ReRAM array, with each of the wordlines comprising a column of memory cell portions communicatively coupled via at least source terminals and drain terminals of column-associated ReRAM elements. For example, in FIG. 10, a vertical collection of ReRAM elements 1050 can comprise a wordline. A plurality of bitlines is provided, each spanning within an associated active layer of the multi-layer ReRAM array, with each of the bitlines comprising a row or plane of gate portions communicatively coupled via at least gate terminals of row/plane-associated ReRAM elements.

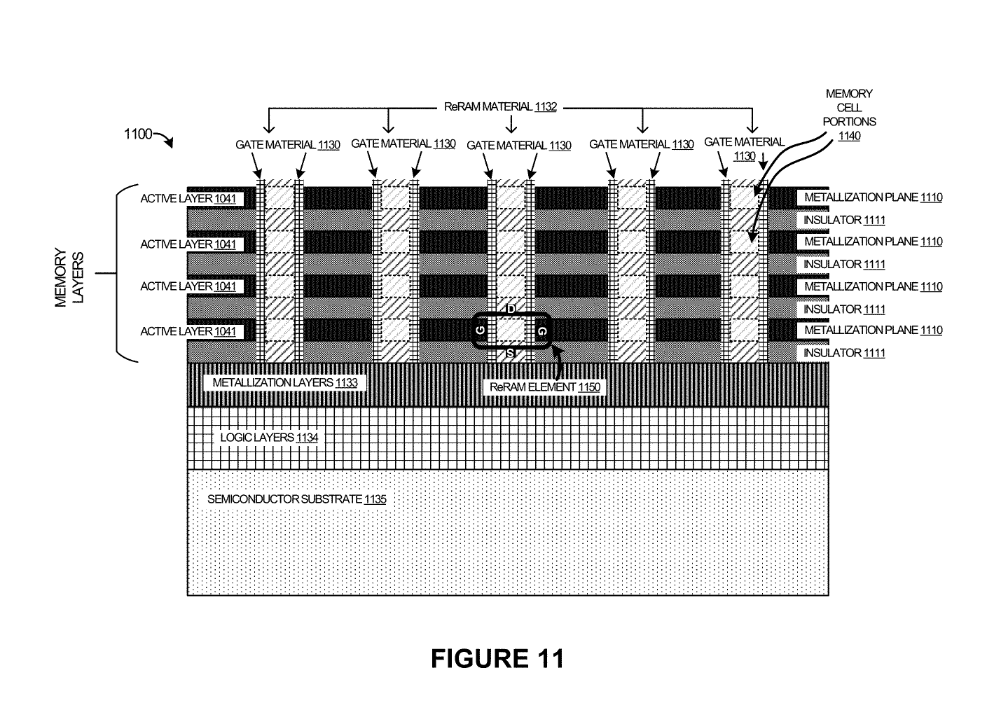

FIG. 11 illustrates another example manufacturing process for a multi-layered or 3D resistive memory array. The compositions of each of the elements of FIG. 11 can comprise any of the materials mentioned herein for associated use in gate materials, insulator materials, resistive memory materials, and metallization materials. Similar procedures as found in FIG. 10 can be followed through view 1001. However, instead of insulating layers alternating with gate layers, FIG. 11 shows insulator planes 1111 interleaved with metallization planes 1110, which can be formed similarly to the planes of FIG. 10. Also, instead of filling the etch-outs 1031 in view 1001 of FIG. 10 with resistive memory material, FIG. 11 illustrates a two-step process. First, a layer of gate material 1130 is deposited onto the inner edges of the etch-out voids, where a specified thickness of the gate material is used to ensure proper control of the resistive properties of associated resistive memory material. ReRAM memory material 1132 is then deposited into the remaining void after the gate material has been deposited to a desired thickness. As seen in FIG. 11, these memory layers can be formed onto a sublayers comprising metallization layers 1133, logic layers 1134, and further substrates such as semiconductor substrate 1135 or a semiconductor wafer.

FIG. 11 shows completed ReRAM structures 1150 in a multi-layered or 3D stacked array similar to as constructed in FIG. 10 but with less gate material employed. Active layers of the multi-layer ReRAM array each comprise a plurality of ReRAM elements 1150 that each include a gate portion formed from deposited gate material 1130. Each of the ReRAM elements have a gate terminal (G) and a memory cell portion 1140 with a source terminal (S) and drain terminal (D). Insulating layers 1111 of the multi-layer ReRAM array alternate with the metallization layers 1110 and insulating material is included between adjacent active layers.

One or more wordlines each comprising ReRAM elements are connected in series by metallized interconnect. The metallized interconnect of each of the wordlines comprising metallizing material introduced between adjacent ReRAM elements to establish a conductive link between the adjacent ReRAM elements. Each of the ReRAM elements comprises a gate portion positioned proximate to the active channel and configured to alter the resistance properties of the active channel responsive to at least voltages applied to the gate portion. Each of the active channels are enveloped by gate material that isolates the active channels from at least the metallization planes. The plurality of wordlines span through more than one layer of the multi-layer ReRAM array, with each of the wordlines comprising a column of memory cell portions communicatively coupled via at least source terminals and drain terminals of column-associated ReRAM elements. For example, in FIG. 11, a vertical collection of ReRAM elements 1150 can comprise a wordline. A plurality of bitlines is provided, each spanning within an associated active layer of the multi-layer ReRAM array, with each of the bitlines comprising a row or plane of gate portions communicatively coupled via at least metallization planes 1110.

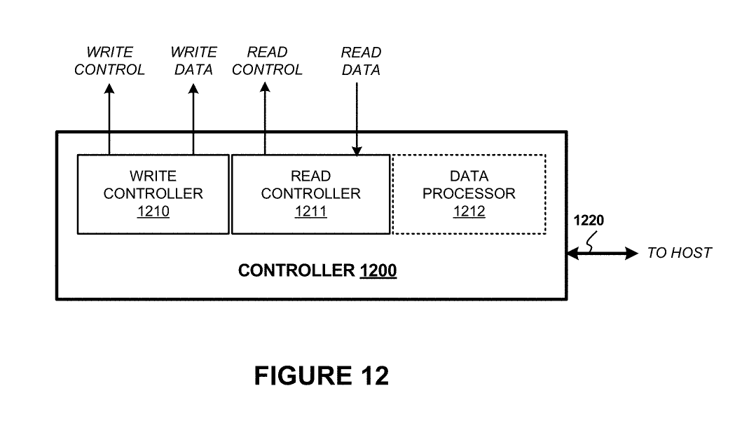

FIG. 12 illustrates controller 1200 that is representative of any logic, control systems, or collection of logic and systems in which the various resistive memory read, write, and other operational architectures, scenarios, and processes disclosed herein may be implemented. For example, controller 1200 can be employed in control system 160 of FIG. 1, or any of the sublayer logic employed in the various figures. Some features of controller 1200 can be incorporated into further devices and systems, such as external controllers, logic modules, microprocessors, computing devices, or distributed computing devices, as well as any variation or combination thereof.

Controller 1200 may be implemented as a single apparatus, system, or device or may be implemented in a distributed manner as multiple apparatuses, systems, or devices. For example, controller 1200 can comprise one or more application-specific integrated circuits (ASICs), field-programmable gate arrays (FPGA), or discrete logic and associated circuitry, including combinations thereof. Although not shown in FIG. 12, controller 1200 can include communication interfaces, network interfaces, user interfaces, and other elements for communicating with a host system over communication link 1220. Controller 1200 may optionally include additional devices, features, or functionality not discussed for purposes of brevity.

Controller 1200 can also comprise or communicate with one or more microcontrollers or microprocessors with software or firmware included on computer-readable storage media devices. If software or firmware is employed, the computer-readable storage media devices may include volatile and nonvolatile, removable and non-removable media implemented in any method or technology for storage of information, such as computer readable instructions, data structures, program modules, or other data. Examples of storage media include random access memory, read only memory, magnetic disks, resistive memory devices, ReRAM devices, optical disks, flash memory, virtual memory and non-virtual memory, magnetic cassettes, magnetic tape, magnetic disk storage or other magnetic storage devices, or any other suitable storage media.

Controller 1200 includes various controller portions to control resistive memory arrays, namely write controller 1210, read controller 1211, and optionally data processor 1212. Write controller 1210 writes data into resistive memory devices discussed herein, such as by using gate features or gate terminals of resistive memory devices. Write control signaling can include bitlines and wordlines which are used to uniquely address a resistive memory device to write data into that resistive memory device. In some examples, only entire wordlines are addressable and thus an entire wordline of data is written into associated resistive memory devices simultaneously. Read controller 1211 reads data stored in resistive memory devices. The read process can include measuring resistance properties of ones of the resistive memory devices. For example, read controller 1211 is communicatively coupled to ends of wordlines or the resistive memory devices and measure at least a series resistance property of each of the wordlines. Read controller 1211 can also be communicatively coupled to ends of the bitlines of the resistive memory devices and individually select ones of the bitlines to measure an associated resistance property of a subset of the resistive memory devices as a series resistance property through a bitline-selected gate portion and a selected wordline. Read controller 1211 can determine data stored by ones of the resistive memory devices by at least processing the series resistance property of a wordline that contains the at least the resistive memory devices being read and a resistance property of a subset of the resistive memory devices being read. Other techniques can be employed to measure and read data from each of the resistive memory devices. Data processor 1212 is optionally included to further process data, such as to arrange data into logical arrangements including words, pages, and the like, before transfer to a host over link 1220. Data processor 1212 can also be configured to perform encoding/decoding or encryption/decryption operations with respect to the data stored in an associated resistive memory array.

The included descriptions and figures depict specific embodiments to teach those skilled in the art how to make and use the best mode. For the purpose of teaching inventive principles, some conventional aspects have been simplified or omitted. Those skilled in the art will appreciate variations from these embodiments that fall within the scope of the invention. Those skilled in the art will also appreciate that the features described above can be combined in various ways to form multiple embodiments. As a result, the invention is not limited to the specific embodiments described above, but only by the claims and their equivalents.

1. A multi-layer resistive random access memory (ReRAM) array, comprising:
active layers of the multi-layer ReRAM array each comprising a plurality of ReRAM elements that each include a gate portion having a gate terminal and a memory cell portion with a source terminal and drain terminal;
insulating layers of the multi-layer ReRAM array that alternate with the active layers and each comprising an insulating material between adjacent active layers;
a plurality of wordlines spanning through more than one layer of the multi-layer ReRAM array, with each of the wordlines comprising a column of memory cell portions coupled via at least source terminals and drain terminals of column-associated ReRAM elements;
a plurality of bitlines each spanning in an associated active layer of the multi-layer ReRAM array, with each of the bitlines comprising a row of gate portions coupled via at least gate terminals of row-associated ReRAM elements.

2. The ReRAM array of claim 1, comprising:
the plurality of wordlines spanning vertically through the more than one layer of the multi-layer ReRAM array, with the vertical direction perpendicular to a surface of a wafer of semiconductor material on which the ReRAM array is formed; and
the plurality of bitlines each spanning horizontally in the associated active layer of the multi-layer ReRAM array, with the horizontal direction parallel to the surface of the wafer.

3. The ReRAM array of claim 1, comprising:
the memory cell portions of each of the ReRAM elements comprising resistive memory material, with resistance properties of the resistive memory material corresponding to data bits stored by the ReRAM elements.

4. The ReRAM array of claim 3, wherein the resistive memory material comprises a flux linkage controlled resistor material.

5. The ReRAM array of claim 1, comprising:
the gate portion of each of the ReRAM elements comprising a wrap-around gate element which envelops the memory cell portion on the associated active layer, with the gate portion of each of the ReRAM elements configured to selectively alter resistance properties of resistive memory material comprising associated memory cell portions.

6. The ReRAM array of claim 5, comprising:
individual ones of the gate portions configured to selectively alter the resistance properties of the associated memory cell portions responsive to at least a voltage applied across a corresponding bitline and wordline.

7. The ReRAM array of claim 1, comprising:
resistive memory material comprising the wordlines that form the columns through the more than one layer of the multi-layer ReRAM array, the resistive memory material penetrating through at least one of the active layers of the multi-layer ReRAM and at least one of the insulating layers of the multi-layer ReRAM array.

8. The ReRAM array of claim 1, comprising:
a semiconductor sublayer on which the multi-layer ReRAM array is layered, the semiconductor sublayer comprising logic circuitry configured to control at least the ReRAM array.

9. The ReRAM array of claim 1, comprising:
the ReRAM elements each comprising non-volatile memory junction field effect transistors, wherein resistances of channel paths of the non-volatile memory junction field effect transistors are altered by at least voltages applied to associated gate portions.

10. The ReRAM array of claim 1, comprising:
control circuitry communicatively coupled to ends of the wordlines and configured to measure at least a series resistance property of each of the wordlines; and
the control circuitry communicatively coupled to ends of the bitlines and configured to individually select ones of the bitlines to measure an associated resistance property of a subset of the ReRAM elements as a series resistance property through a bitline-selected gate portion and a selected wordline;
the control circuitry configured to determine data stored by a first of the ReRAM elements by at least processing the series resistance property of a first wordline that contains the at least one of the ReRAM elements and a resistance property of a first subset of the ReRAM elements.

11. A resistive memory storage array, comprising:
a plurality of metallization planes interleaved with a plurality of insulating planes that form a vertically layered stackup of planar material;
a plurality of active channels comprising resistive memory material and disposed vertically through the layered stackup of planar material to establish vertical wordlines of the resistive memory storage array, with each of the active channels enveloped by gate material that isolates the active channels from at least the metallization planes; and
individual resistive memory cells defined by the gate material and proximate portions of the active channels on layers comprising the metallization planes, with the gate material of the resistive memory cells communicatively coupled by associated metallization planes to establish a plurality of horizontal bitlines.

12. The resistive memory storage array of claim 11, comprising:
each of the resistive memory cells configured to alter resistance properties of the resistive memory material in an associated active channel responsive to at least a voltage applied to associated gate material, with the resistance properties corresponding to at least one data bit.

13. The resistive memory storage array of claim 11, comprising:
the layered stackup of planar material further layered onto a semiconductor sublayer, the semiconductor sublayer comprising logic circuitry configured to control at least the resistive memory storage array.

14. The resistive memory storage array of claim 11, wherein the resistive memory material comprises a flux linkage controlled resistor material.

15. The resistive memory storage array of claim 11, comprising:
control circuitry communicatively coupled to ends of the wordlines and configured to measure at least a series resistance property of each of the wordlines; and
the control circuitry communicatively coupled to ends of the bitlines and configured to individually select ones of the bitlines to measure an associated resistance property of a subset of the resistive memory cells as a series resistance property through a bitline-selected gate portion and a selected wordline;
the control circuitry configured to determine data stored by a first of the resistive memory cells by at least processing the series resistance property of a first wordline that contains the at least one of the resistive memory cells and a resistance property of a first subset of the resistive memory cells.

16. A method of manufacturing a multi-layer resistive random access memory (ReRAM) array, the method comprising:
forming a plurality of metallization planes interleaved with a plurality of insulating planes to establish a vertically layered stackup of planar material;
forming a plurality of active channels comprising resistive memory material disposed vertically through the layered stackup of planar material to establish vertical wordlines of the resistive memory storage array, with each of the active channels enveloped by gate material that isolates the active channels from at least the metallization planes; and
wherein individual resistive memory cells are defined by the gate material and proximate portions of the active channels on layers comprising the metallization planes, with the gate material of the resistive memory cells communicatively coupled by associated metallization planes to establish a plurality of horizontal bitlines.

17. The method of claim 16, further comprising:
forming the layered stackup of planar material onto at least one of a semiconductor sublayer and a metallization layer associated with the underlying semiconductor sublayer.

18. The method of claim 17, further comprising:
forming interconnect that communicatively couples the wordlines and bitlines to control logic of the semiconductor sublayer.

19. The method of claim 16, wherein the resistive memory material comprises a flux linkage controlled resistor material.

20. The method of claim 16, wherein the gate material comprises an n-type polycrystalline silicon material.
